(19) United States
(12) Patent Application Publication
(10) Pub. No.: US 2021/0223329 A1
(43) Pub. Date: Jul. 22, 2021

(54) SYMMETRIC METHOD FOR OBTAINING BUS-TRANSLATION-VOLTAGE COMPONENTS INDUCED BY SOURCES AND LOADS AT INDIVIDUAL BUSES IN AC POWER NETWORKS

(71) Applicant: SHENZHEN UNIVERSITY, Shenzhen, Guangdong (CN)

(72) Inventors: Jianchun PENG, Shenzhen, Guangdong (CN); Hui JIANG, Shenzhen, Guangdong (CN); Huaizhi WANG, Shenzhen, Guangdong (CN)

(73) Assignee: SHENZHEN UNIVERSITY, Shenzhen, Guangdong (CN)

(21) Appl. No.: 16/630,215

(22) PCT Filed: Jan. 28, 2019
(86) PCT No.: PCT/CN2019/073443

§ 371 Date: Jan. 10, 2020

(51) Int. Cl. G01R 31/42; H02J 13/00; G01R 19/25

(52) U.S. Cl. CPC G01R 31/42; H02J 2203/20; G01R 19/25; H02J 13/00002

(57) ABSTRACT

A symmetric method for obtaining bus-translation-voltage components induced by sources and loads at individual buses in AC power networks is invented. Two linear expressions of bus injection active and reactive powers in terms of translation voltages and voltage angles of all buses are established according to branch admittances and bus injection powers of sources and loads. Then a linear symmetric matrix-equation model for the steady state of the network is built. Manipulating this model by Moore-Penrose pseudoinverse produces a linear symmetric matrix expression of translation voltages and voltage angles of all buses in terms of bus injection powers. Finally a linear symmetric algebraic calculation formula for obtaining the bus-translation-voltage components is extracted from this matrix expression to achieve obtaining of the bus-translation-voltage components. The set of bus-translation-voltage components provides a new tool for efficiently and accurately regulating bus voltages and guaranteeing good power quality of AC power networks.

### TECHNICAL FIELD

The present application relates to electric power engineering field, and more particularly to a symmetric method for obtaining bus-translation-voltage components induced by (power) sources and loads at individual buses in alternating current (AC) power networks and a computer-readable storage medium.

### BACKGROUND

In the AC power network, the concise and precise relation between bus voltages (effective value) and powers of sources and loads is a key to efficiently regulate bus voltages and ensure the quality of electricity. The set of bus-translation-voltage components induced by sources and loads at individual buses is a new concise and precise tool for efficiently expressing bus voltages. It is thus expected to be developed urgently.

The existing bus voltage regulating methods for AC power networks fall into two categories. One is implemented by constructing a reactive power optimization model and then obtaining a regulation scheme through optimization. The other is implemented by obtaining a set of sensitivities of bus voltages to the powers of sources and loads and then using the sensitivity-based approximate linear relation. Due to the non-linearity of the reactive power optimization model, the former is not only unable to guarantee that the voltage control scheme can be obtained reliably, but the computational effort for solving this optimization model is always large. Owing to the local linearity feature of the sensitivities, the latter just achieves an inaccurate bus voltage regulation and consequently cause repeated regulation.

Therefore, the existing bus voltage regulating methods for AC power networks are either time-consuming and unreliable, or inaccurate and inefficient.

### SUMMARY

An embodiment of the present application provides a symmetric method for obtaining bus-translation-voltage components induced by sources and loads at individual buses in AC power networks and a computer-readable storage medium, which aims to solve the problems of low efficiency and unreliability inherent in the existing bus voltage regulating methods for AC power networks.

A first aspect of the embodiment of the present application provides a symmetric method for obtaining bus-translation-voltage components induced by sources and loads at individual buses in an AC power network, which comprises the following steps:

establishing two linear expressions of bus injection active and reactive powers of sources and loads in terms of translation voltages and voltage angles of all buses according to bus injection powers of sources and loads and branch admittances in the AC power network;

establishing a linear symmetric matrix-equation model for the steady state of the AC power network according to the two linear expressions of bus injection active and reactive powers of sources and loads in terms of translation voltages and voltage angles of all buses;

establishing a linear symmetric matrix expression of translation voltages and voltage angles of all buses in terms of bus injection active and reactive powers of all sources and loads according to the linear symmetric matrix-equation model for the steady state of the AC power network by using the Moore-Penrose pseudoinverse of a matrix; and

establishing a linear symmetric algebraic calculation formula for obtaining the bus-translation-voltage components induced by sources and loads at individual buses according to the linear symmetric matrix expression of translation voltages and voltage angles of all buses in terms of bus injection active and reactive powers of all sources and loads.

A second aspect of the embodiment of the present application provides a computer-readable storage medium on which a computer program is stored. The computer program, when executed by a processor, implements the steps of the above symmetric method for obtaining the bus-translation-voltage components induced by sources and loads at individual buses in the AC power network.

During the implementation of the above symmetric method, the bus-translation-voltage components induced by sources and loads at individual buses in the AC power network are obtained according to the linear symmetric algebraic calculation formula for obtaining the bus-translation-voltage components induced by sources and loads at individual buses. On the one hand, since the linear symmetric algebraic calculation formula for obtaining the bus-translation-voltage components induced by sources and loads at individual buses is applicable to all buses in the AC power network, and all bus injection powers of sources and loads are identically treated in it, the bus-translation-voltage components induced by sources and loads at individual buses are symmetric for all sources and loads. On the other hand, as the linear symmetric algebraic calculation formula for obtaining the bus-translation-voltage components induced by sources and loads at individual buses is in terms of the global (not incremental) variables representing the bus injection powers of sources and loads, it is accurate for wide range change of the bus injection powers of sources and loads and reduces the computational effort. This symmetric and accurate relation between the bus-translation-voltage components and the bus injection powers of sources and loads solves the problems of the time-consuming, unreliability, inaccuracy and inefficiency inherent in the existing bus voltage regulating methods for AC power networks.

### BRIEF DESCRIPTION OF THE DRAWINGS

In order to explain the technical solution of embodiments of the present application more clearly, the drawings used in the description of the embodiments will be briefly described hereinbelow. Obviously, the drawings in the following description are some embodiments of the present application, and for persons skilled in the art, other drawings may also be obtained on the basis of these drawings without any creative work.

FIG. 1 is an implementation flow chart of a symmetric method for obtaining bus-translation-voltage components induced by sources and loads at individual buses in an AC power network in accordance with an embodiment of the present application; and

FIG. 2 is a structural schematic diagram of a universal mode of an AC power network in accordance with an embodiment of the present application.

### DETAILED DESCRIPTION OF THE EMBODIMENTS

In the description hereinbelow, for purposes of explanation rather than limitation, specific details such as specific systematic architectures and techniques are set forth in order to provide a thorough understanding of the embodiments of the present application. However, it will be apparent to persons skilled in the art that the present application may also be implemented in absence of such specific details in other embodiments. In other instances, detailed descriptions of well-known systems, devices, circuits and methods are omitted so as not to obscure the description of the present application with unnecessary detail.

Technical solution of the present application is explained hereinbelow by particular embodiments.

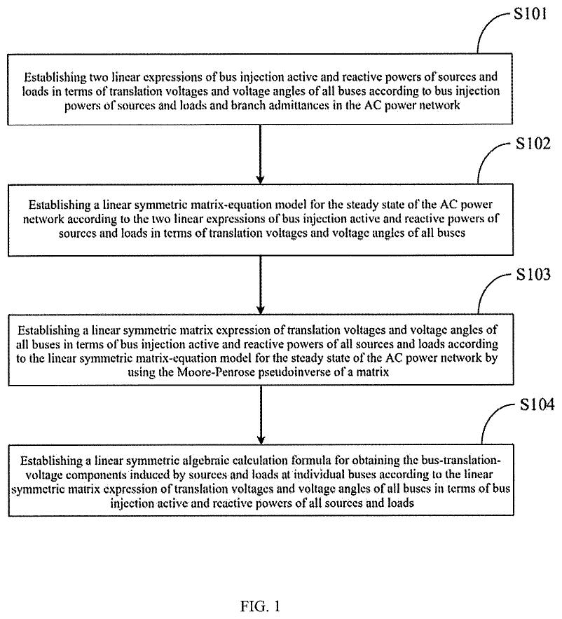

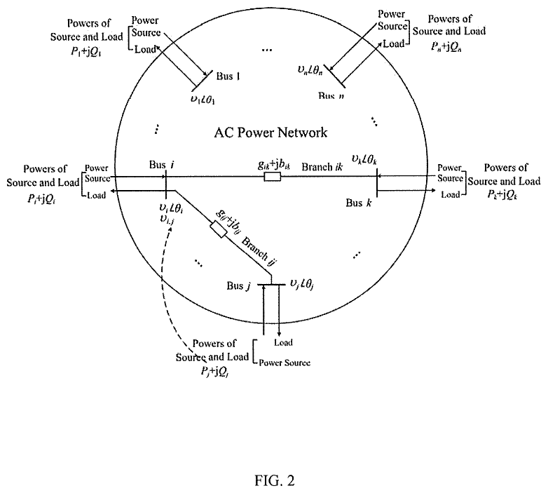

Please refer to FIG. 1 and FIG. 2, the symmetric method for obtaining bus-translation-voltage components induced by sources and loads at individual buses in the AC power network may be conducted according to the following steps:

in step S101, two linear expressions of bus injection active and reactive powers of sources and loads in terms of translation voltages and voltage angles of all buses are established according to bus injection powers of sources and loads and branch admittances in the AC power network;

in step S102, a linear symmetric matrix-equation model for the steady state of the AC power network is established according to the two linear expressions of bus injection active and reactive powers of sources and loads in terms of translation voltages and voltage angles of all buses;

in step S103, a linear symmetric matrix expression of translation voltages and voltage angles of all buses in terms of bus injection active and reactive powers of all sources and loads is established according to the linear symmetric matrix-equation model for the steady state of the AC power network by using the Moore-Penrose pseudoinverse of a matrix; and

in step S104, a linear symmetric algebraic calculation formula for obtaining the bus-translation-voltage components induced by sources and loads at individual buses is established according to the linear symmetric matrix expression of translation voltages and voltage angles of all buses in terms of bus injection active and reactive powers of all sources and loads.

Calculating using the above linear symmetric algebraic calculation formula for all bus translation voltages and all bus injection powers of sources and loads at individual buses in the AC power network will produce a set of bus-translation-voltage components induced by sources and loads at individual buses, such that the bus-translation-voltage components induced by sources and loads at individual buses in the AC power network are obtained. This symmetric and accurate relation between the bus-translation-voltage components and the bus injection powers of sources and loads at individual buses solves the problems of the time-consuming, unreliability, inaccuracy and inefficiency inherent in the existing bus voltages regulating methods for AC power networks.

The step S101 of establishing the two linear expressions of bus injection active and reactive powers of sources and loads in terms of translation voltages and voltage angles of all buses according to bus injection powers of sources and loads and branch admittances in the AC power network is specifically as follows:

the two linear expressions of bus injection active and reactive powers of sources and loads in terms of translation voltages and voltage angles of all buses are established by the following equations:

$${P}_{i} = {\sum }_{k = 1 k \neq i}^{n} ( - {θ}_{i} {b}_{ik} + {v}_{i} {g}_{i k} + {θ}_{k} {b}_{ik} - {v}_{k} {g}_{i k} )$$

$${Q}_{i} = {\sum }_{k = 1 k \neq i}^{n} ( - {θ}_{i} {g}_{ik} - {v}_{i} {b}_{i k} + {θ}_{k} {g}_{ik} - {v}_{k} {b}_{i k} )$$

in which, both i and k denote serial numbers of buses in the AC power network and belong to the set of continuous natural numbers, namely belong to {1, 2, . . . , n}; n denotes the total number of buses in the AC power network; Pᵢ and Qᵢ denote the active and reactive powers of the source and load at bus i, respectively, and referred to collectively as the powers of the source and load at bus i; the Pᵢ equals to the active power of the power source minus the active power of the load at bus i; the Qᵢ equals to the reactive power of the power source minus the reactive power of the load at bus i; gᵢₖ and bᵢₖ denote the conductance and susceptance of branch ik connected between bus i and bus k, respectively, and referred to collectively as the admittance of branch ik; θᵢ and θₖ denote the voltage angles at bus i and bus k, respectively; νᵢ and νₖ denote the translation voltages at bus i and bus k, respectively, and both νᵢ and νₖ are per-unit voltages translated by −1.0.

The step S102 of establishing the linear symmetric matrix-equation model for the steady state of the AC power network according to the two linear expressions of bus injection active and reactive powers of sources and loads in terms of translation voltages and voltage angles of all buses is specifically as follows:

the linear symmetric matrix-equation model for the steady state of the AC power network is established by the following equation:

[P₁Q₁ . . . PᵢQᵢ . . . PₙQₙ]^{T}=(G_{*,*})[θᵢνᵢ . . . θₙν₁ . . . θₙνₙ]^{T}

where (G_{*,*}) is set to zero at first, and then the branches are scanned and the accumulations are done as follows: G_{2i-1,2i-1}=G_{2i-1,2i-1}−bᵢⱼ, G_{2i-1,2i}=G_{2i-1,2i}+gᵢⱼ, G_{2i-1,2j-1}=G_{2i-1,2j-1}+bᵢⱼ, G_{2i-1,2j}=G_{2i-1,2j}−gᵢⱼ, G_{2i,2i-1}=G_{2i,2i-1}−gᵢⱼ, G_{2i,2i}=G_{2i,2i}−bᵢⱼ, G_{2i,2j-1}=G_{2i,2j-1}+gᵢⱼ, G_{2i,2j}=G_{2i,2j}+bᵢⱼ.

in which, both i and j denote serial numbers of buses in the AC power network and belong to the set of continuous natural numbers, namely belong to {1,2, . . . , n}; n denotes the total number of buses in the AC power network; P₁ and Q₁ denote the active and reactive powers of the source and load at bus 1, respectively, and referred to collectively as the powers of the source and load at bus 1; the P₁ equals to the active power of the power source minus the active power of the load at bus 1; the Q₁ equals to the reactive power of the power source minus the reactive power of the load at bus 1; Pᵢ and Qᵢ denote the active and reactive powers of the source and load at bus i, respectively, and referred to collectively as the powers of the source and load at bus i; the Pᵢ equals to the active power of the power source minus the active power of the load at bus i; the Qᵢ equals to the reactive power of the power source minus the reactive power of the load at bus i; Pₙ and Qₙ denote the active and reactive powers of the source and load at bus n, respectively, and referred to collectively as the powers of the source and load at bus n; the Pₙ equals to the active power of the power source minus the active power of the load at bus n; the Qₙ equals to the reactive power of the power source minus the reactive power of the load at bus n; gᵢⱼ and bᵢⱼ denote the conductance and susceptance of branch ij connected between bus i and bus j, and referred to collectively as the admittance of branch ij; θ₁, θᵢ and θₙ denote the voltage angles at bus 1, bus i and bus n, respectively; ν₁, νᵢ and νₙ denote the translation voltages at bus 1, bus i and bus n, respectively, and the ν₁, νᵢ and νₙ are all per-unit voltages translated by −1.0. (G_{*,*}) is the full bus admittance matrix with a dimension of 2n×2n; G_{2i-1,2i-1}, G_{2i-1,2i}, G_{2i-1,2j-1}, G_{2i-1,2j}, G_{2i,2i-1}, G_{2i,2i}, G_{2i,2j-1} and G_{2i,2j} are the row-2i−1 and column-2i−1, the row-2i−1 and column-2i, the row-2i−1 and column-2j−1, the row-2i−1 and column-2j, the row-2i and column-2i−1, the row-2i and column-2i, the row-2i and column-2j 1 and the row-2 i and column-2j elements of the full bus admittance matrix (G_{*,*}) respectively.

In the above linear matrix-equation model for the steady state of the AC power network, all bus injection powers of sources and loads at individual buses are introduced and identically treated without any bias, namely symmetrically treated. This is the reason why the above model is called the linear symmetric matrix-equation model.

The step S103 of establishing the linear symmetric matrix expression of translation voltages and voltage angles of all buses in terms of bus injection active and reactive powers of all sources and loads according to the linear symmetric matrix-equation model for the steady state of the AC power network by using the Moore-Penrose pseudoinverse of a matrix is specifically as follows:

the linear symmetric matrix expression of translation voltages and voltage angles of all buses in terms of bus injection active and reactive powers of all sources and loads is established by the following equations:

[θ₁ν₁ . . . θᵢνᵢ . . . θₙνₙ]^{T}=(a_{*,*})[P₁Q₁ . . . PᵢQᵢ . . . PₙQₙ]^{T}

(a_{*,*})=(G_{*,*})⁺

in which, i denotes the serial number of a bus in the AC power network and belongs to the set of continuous natural numbers, namely belong to {1, 2, . . . , n}; n denotes the total number of buses in the AC power network; θ₁, θᵢ and θₙ denote the voltage angles at bus 1, bus i and bus n, respectively; ν₁, νᵢ and νₙ denote the translation voltages at bus 1, bus i and bus n, respectively, and the ν₁, νᵢ and νₙ are all per-unit voltages translated by −1.0; P₁ and Q₁ denote the active and reactive powers of the source and load at bus 1, respectively, and referred to collectively as the powers of the source and load at bus 1; the P₁ equals to the active power of the power source minus the active power of the load at bus 1; the Q₁ equals to the reactive power of the power source minus the reactive power of the load at bus 1; Pᵢ and Qᵢ denote the active and reactive powers of the source and load at bus i, respectively, and referred to collectively as the powers of the source and load at bus i; the Pᵢ equals to the active power of the power source minus the active power of the load at bus i; the Qᵢ equals to the reactive power of the power source minus the reactive power of the load at bus i; Pₙ and Qₙ denote the active and reactive powers of the source and load at bus n, respectively, and referred to collectively as the powers of the source and load at bus n; the Pₙ equals to the active power of the power source minus the active power of the load at bus n; the Qₙ equals to the reactive power of the power source minus the reactive power of the load at bus n; (G_{*,*}) is the full bus admittance matrix with a dimension of 2n×2n; the superscript symbol + is an operator to find the Moore-Penrose pseudoinverse of a matrix; and (a_{*,*}) denotes the Moore-Penrose pseudoinverse of the full bus admittance matrix (G_{*,*}).

The step S104 of establishing the linear symmetric algebraic calculation formula for obtaining the bus-translation-voltage components induced by sources and loads at individual buses according to the linear symmetric matrix expression of translation voltages and voltage angles of all buses in terms of bus injection active and reactive powers of all sources and loads is specifically as follows:

the linear symmetric algebraic calculation formula for obtaining the bus-translation-voltage components induced by sources and loads at individual buses is established by the following equation:

ν_{i,j}=a_{2i,2j-1}Pⱼ+a_{2i,2j}Qⱼ

in which, both i and j denote serial numbers of buses in the AC power network and belong to the set of continuous natural numbers, namely belong to {1, 2, . . . , n}; n denotes the total number of buses in the AC power network; ν_{i,j} is the bus-translation-voltage component at bus i induced by the power source and load at bus j, and referred to as the bus-translation-voltage component induced by the power source and load, and the ν_{i,j} is a per-unit voltage translated by −1.0; a_{2i,2j-1} and a_{2i,2j} denote the row-2i and column-2j−1 and the row-2i and column-2j elements of the Moore-Penrose pseudoinverse of the full bus admittance matrix with a dimension of 2n×2n, respectively; Pⱼ and Qⱼ denote the active and reactive powers of the source and load at bus j, respectively, and referred to collectively as the powers of the source and load at bus j; the Pⱼ equals to the active power of the power source minus the active power of the load at bus j; the Qⱼ equals to the reactive power of the power source minus the reactive power of the load at bus j.

The above linear symmetric algebraic calculation formula for obtaining the bus-translation-voltage components induced by sources and loads at individual buses is applicable to all buses in the AC power network, and all bus injection powers of sources and loads are identically treated in it. This is the reason why the present application is called a symmetric method for obtaining bus-translation-voltage components induced by sources and loads at individual buses in AC power networks. Moreover, as the linear symmetric algebraic calculation formula for obtaining the bus-translation-voltage components induced by sources and loads at individual buses is in terms of the global (not incremental) variables representing the bus injection powers of sources and loads, it is accurate for wide range change of the bus injection powers of sources and loads. This symmetric and accurate relation between the bus-translation-voltage components and the bus injection powers of the sources and loads solves the problems of the time-consuming, unreliability, inaccuracy and inefficiency inherent in the existing bus voltage regulating methods for AC power networks.

An embodiment of the present application provides a computer-readable storage medium on which a computer program is stored. The computer program may be a source code program, an object code program, an executable file or some intermediate form. the computer program can carry out the steps of the symmetric method for obtaining the bus-translation-voltage components induced by sources and loads at individual buses in the AC power network as described in the above embodiments when implemented by a processor. The computer-readable storage medium may include any entity or device capable of carrying computer programs, such as a U disk, a mobile hard disk, an optical disk, a computer memory, a random-access memory and the like.

The embodiments disclosed herein are merely used to illustrate the technical solutions of the present application, but not aimed to limit the present application. Although the present application is described in detail with reference to the foregoing embodiments, it should be understood for persons skilled in the art that modifications, or equivalent replacements of some of the technical features can be implemented under the spirit of the present application, and these modifications or replacements do not deviate the essence of the corresponding technical solutions from the spirit and scope of the technical solutions of the embodiments of the present application, and should be included by the protection scope of the present application.

1. A symmetric method for obtaining bus-translation-voltage components induced by sources and loads at individual buses in an AC power network, comprising the following steps:
establishing two linear expressions of bus injection active and reactive powers of sources and loads in terms of translation voltages and voltage angles of all buses according to bus injection powers of sources and loads and branch admittances in the AC power network;
establishing a linear symmetric matrix-equation model for the steady state of the AC power network according to the two linear expressions of bus injection active and reactive powers of sources and loads in terms of translation voltages and voltage angles of all buses;
establishing a linear symmetric matrix expression of translation voltages and voltage angles of all buses in terms of bus injection active and reactive powers of all sources and loads according to the linear symmetric matrix-equation model for the steady state of the AC power network by using the Moore-Penrose pseudoinverse of a matrix; and
establishing a linear symmetric algebraic calculation formula for obtaining the bus-translation-voltage components induced by sources and loads at individual buses according to the linear symmetric matrix expression of translation voltages and voltage angles of all buses in terms of bus injection active and reactive powers of all sources and loads.

2. The symmetric method according to claim 1, wherein the step of establishing the two linear expressions of the bus injection active and reactive powers of sources and loads in terms of translation voltages and voltage angles of all buses according to the bus injection powers of sources and loads and branch admittances in the AC power network comprises:
establishing the two linear expressions of the bus injection active and reactive powers of sources and loads in terms of translation voltages and voltage angles of all buses by the following equations:
$${P}_{i} = {\sum }_{k = 1 k \neq i}^{n} ( - {θ}_{i} {b}_{ik} + {v}_{i} {g}_{i k} + {θ}_{k} {b}_{ik} - {v}_{k} {g}_{i k} )$$
$${Q}_{i} = {\sum }_{k = 1 k \neq i}^{n} ( - {θ}_{i} {g}_{ik} - {v}_{i} {b}_{i k} + {θ}_{k} {g}_{ik} - {v}_{k} {b}_{i k} )$$
wherein, both i and k denote serial numbers of buses in the AC power network and belong to the set of continuous natural numbers, namely belongs to {1, 2, . . . , n}; n denotes the total number of buses in the AC power network; Pᵢ and Qᵢ denote the active and reactive powers of the source and load at bus i, respectively, and referred to collectively as the powers of the source and load at bus i; gᵢₖ and bᵢₖ denote the conductance and susceptance of branch ik connected between bus i and bus k, respectively, and referred to collectively as the admittance of branch ik; θᵢ and θₖ denote the voltage angles at bus i and bus k, respectively; and νᵢ and νₖ denote the translation voltages at bus i and bus k, respectively, and both the νᵢ and νₖ are per-unit voltages translated by −1.0.

3. The symmetric method according to claim 1, wherein the step of establishing the linear symmetric matrix-equation model for the steady state of the AC power network according to the two linear expressions of bus injection active and reactive powers of sources and loads in terms of translation voltages and voltage angles of all buses comprises:
establishing the linear symmetric matrix-equation model for the steady state of the AC power network by the following equation:
[P₁Q₁ . . . PᵢQᵢ . . . PₙQₙ]^{T}=(G_{*,*})[θᵢνᵢ . . . θᵢνᵢ . . . θₙνₙ]^{T}
wherein is set to zero at first, and then the branches are scanned and accumulated as follows: G_{2i-1,2i-1}=G_{2i-1,2i-1}−bᵢⱼ, G_{2i-1,2i}=G_{2i-1,2i}+gᵢⱼ, G_{2i-1,2j-1}=G_{2i-1,2j-1}+bᵢⱼ, G_{2i-1,2j}=G_{2i-1,2j}−gᵢⱼ, G_{2i,2i-1}=G_{2i,2i-1}−gᵢⱼ, G_{2i,2i}=G_{2i,2i}−bᵢⱼ, G_{2i,2j-1}=G_{2i,2j-1}+gᵢⱼ, G_{2i,2j}=G_{2i,2j}+bᵢⱼ; and
wherein, both i and j denote serial numbers of buses in the AC power network and belong to the set of continuous natural numbers, namely belong to {1, 2, . . . , n}; n denotes the total number of buses in the AC power network; P₁ and Q₁ denote the active and reactive powers of the source and load at bus 1, respectively, and referred to collectively as the powers of the source and load at bus 1; P₁ and Q₁ denote the active and reactive powers of the source and load at bus i, respectively, and referred to collectively as the powers of the source and load at bus i; Pₙ and Qₙ denote the active and reactive powers of the source and load at bus n, respectively, and referred to collectively as the powers of the source and load at bus n; gᵢⱼ and bᵢⱼ denote the conductance and susceptance of branch ij connected between bus i and bus j, and referred to collectively as the admittance of branch ij; θ₁, θᵢ and θₙ denote the voltage angles at bus 1, bus i and bus n, respectively; νᵢ, νᵢ and νₙ denote the translation voltages at bus 1, bus i and bus n, respectively, and the νᵢ, νᵢ and νₙ are all per-unit voltages translated by −1.0; (G_{*,*}) is the full bus admittance matrix with a dimension of 2n×2n; and G_{2i-1,2i-1}, G_{2i-1,2i}, G_{2i-1,2j-1}, G_{2i-1,2j}, G_{2i,2i-1}, G_{2i,2i}, G_{2i,2j-1} and G_{2i,2j} are elements of the full bus admittance matrix (G_{*,*}).

4. The symmetric method according to claim 1, wherein the step of establishing the linear symmetric matrix expression of translation voltages and voltage angles of all buses in terms of bus injection active and reactive powers of all sources and loads according to the linear symmetric matrix-equation model for the steady state of the AC power network by using the Moore-Penrose pseudoinverse of a matrix comprises:
establishing the linear symmetric matrix expression of translation voltages and voltage angles of all buses in terms of bus injection active and reactive powers of all sources and loads by the following equations:
[θ₁ν₁ . . . θᵢνᵢ . . . θₙνₙ]^{T}=(a_{*,*})[P₁Q₁ . . . PᵢQᵢ . . . PₙQₙ]^{T}
(a_{*,*})=(G_{*,*})⁺
wherein, i denotes the serial number of a bus in the AC power network and belongs to the set of continuous natural numbers, namely belong to {1, 2, . . . , n}; n denotes the total number of buses in the AC power network; θ₁, θᵢ and θₙ denote the voltage angles at bus 1, bus i and bus n, respectively; νᵢ, νᵢ and νₙ denote the translation voltages at bus 1, bus i and bus n, respectively, and the ν₁, νᵢ and νₙ are all per-unit voltages translated by −1.0; P₁ and Q₁ denote the active and reactive powers of the source and load at bus 1, respectively, and referred to collectively as the powers of the source and load at bus 1; Pᵢ and Qᵢ denote the active and reactive powers of the source and load at bus i, respectively, and referred to collectively as the powers of the source and load at bus i; Pₙ and Qₙ denote the active and reactive powers of the source and load at bus n, respectively, and referred to collectively as the powers of the source and load at bus n; is the full bus admittance matrix with a dimension of 2n×2n; the superscript symbol + is an operator to find the Moore-Penrose pseudoinverse of a matrix; (a_{*,*}) and denotes the Moore-Penrose pseudoinverse of the full bus admittance matrix (G_{*,*}).

5. The symmetric method according to claim 1, wherein the step of establishing the linear symmetric algebraic calculation formula for obtaining the bus-translation-voltage components induced by sources and loads at individual buses according to the linear symmetric matrix expression of translation voltages and voltage angles of all buses in terms of bus injection active and reactive powers of all sources and loads comprises:
establishing the linear symmetric algebraic calculation formula for obtaining the bus-translation-voltage components induced by sources and loads at individual buses by the following equation:
ν_{i,j}=a_{2i,2j-1}Pⱼ+a_{2i,2j}Qⱼ
wherein, both i and j denote serial numbers of buses in the AC power network and belong to the set of continuous natural numbers, namely belong to {1, 2, . . . , n}; n denotes the total number of buses in the AC power network; ν_{i,j} is the bus-translation-voltage component at bus i induced by the power source and load at bus j, and referred to as the bus-translation-voltage component induced by the power source and load, and the is a per-unit voltage translated by −1.0; a_{2i,2j-1} and a_{2i,2j} are elements of the Moore-Penrose pseudoinverse of the full bus admittance matrix with a dimension of 2n×2n; Pⱼ and Qⱼ denote the active and reactive powers of the source and load at bus j, respectively, and referred to collectively as the powers of the source and load at bus j.

6. A computer-readable storage medium, on which a computer program is stored, wherein the computer program can carry out the steps of the symmetric method for obtaining the bus-translation-voltages components induced by sources and loads at individual buses in the AC power network according to claim 1 when implemented by a processor.
